(19) United States
(12) Patent Application Publication
(10) Pub. No.: US 2026/0243829 A1
(43) Pub. Date: Aug. 20, 2026

(54) METHOD FOR MEASURING A COLLECTOR CURRENT OF A SEMICONDUCTOR SWITCH BY MEANS OF A MEASURING RESISTOR

(71) Applicant: Robert Bosch GmbH, Stuttgart (DE)

(72) Inventor: Attila Hollosi, Budapest (HU)

(21) Appl. No.: 19/054,253

(22) Filed: Feb. 14, 2025

(30) Foreign Application Priority Data
Feb. 22, 2024 (DE) 10 2024 201 604.7

(51) Int. Cl. G01R 31/327; G01R 15/14; G01R 35/00

(52) U.S. Cl. CPC G01R 31/3277; G01R 15/146; G01R 35/005

(57) ABSTRACT

A method for measuring a collector current of a semiconductor switch. The method includes: ascertaining a value of the measuring resistor; measuring a voltage drop across the measuring resistor, which is connected between an emitter terminal of a measuring semiconductor switch of the semiconductor switch and an emitter terminal of a main semiconductor switch of the semiconductor switch; ascertaining a measuring current from a quotient of the voltage drop across the measuring resistor and the value of the measuring resistor; ascertaining a gate voltage of the measuring semiconductor switch based on an area-adjusted current value and a transfer function; ascertaining a gate voltage of the main semiconductor switch; and ascertaining a collector current of the main semiconductor switch based on the ascertained gate voltage of the main semiconductor switch and the transfer function.

### FIELD

The present invention relates to a method for measuring a collector current of a semiconductor switch by means of a measuring resistor.

### BACKGROUND INFORMATION

Power modules in which a plurality of power semiconductor switches such as IGBTs designed as chips are connected in parallel are described in the related art.

For various reasons, it may be important to obtain information about the distribution of a total current flowing through the power module to the individual chips. There may be cases in which a particularly uniform distribution across the respective parallel-connected chips is desired, but there may also be cases in which a non-uniform distribution is to be achieved.

A measurement of the current distribution in such a power module is conventionally carried out on the basis of open power modules, which are not packaged in a housing. As a result, it is possible, for example, to insert a so-called Rogowski coil between the chips in order to measure the current flowing through the respective chips independently of one another.

### SUMMARY

A method according to the present invention for measuring a collector current of a semiconductor switch by means of a measuring resistor offers the particular advantage that this method can be carried out in connection with semiconductor chips and/or semiconductor modules which may be enclosed by a housing, in particular by an injection-molded housing, so that conventional measurement by means of a Rogowski coil is not possible.

It should be noted in general that the method steps described below can be carried out at least partially on the basis of an evaluation unit that, for example, executes a computer program that implements the method steps according to the present invention.

According to an example embodiment of the present invention, in a first step of the method according to the present invention, a resistance value of the measuring resistor is ascertained. This is preferably effected on the basis of a four-wire measurement in order to achieve a particularly accurate measurement result. During this step, the measuring resistor is preferably separated from other components (e.g., physically separated or separated by a suitable separating device such as a switch, in particular a mechanical and/or electromagnetic switch, etc.), so that it can be measured by means of a suitable measuring arrangement without disturbing influences from other components.

In a second step of the method according to the present invention, a voltage drop across the measuring resistor is measured in a state in which the measuring resistor is connected between an emitter terminal of a measuring semiconductor switch of the semiconductor switch and an emitter terminal of a main semiconductor switch of the semiconductor switch, wherein respective collector terminals of the main semiconductor switch and the measuring semiconductor switch and respective gate terminals of the main semiconductor switch and the measuring semiconductor switch are electrically connected to one another and wherein a direct voltage is applied between the collector terminals and the emitter terminals.

The measuring semiconductor switch and the main semiconductor switch are preferably formed by means of the same process technology and more preferably on a single substrate, so that they represent, for example, a single chip.

The main semiconductor switch has a first area, which is larger than a second area of the measuring semiconductor switch. Preferably, the first area is substantially larger than the second area, so that only a small current flows through the measuring semiconductor switch, which is connected in parallel to the main semiconductor switch. For example, a ratio of the first area to the second area corresponds to a factor of 1000, without thereby imposing a restriction on such an area ratio.

In a third step of the method according to the present invention, a measuring current is ascertained from a quotient of the voltage drop across the measuring resistor and the resistance value of the measuring resistor as follows:

$$Is = \frac{Us}{Rs}$$

where Is represents the measuring current, Us the measured voltage drop and Rs the resistance value of the measuring resistor.

In a fourth step of the method according to the present invention, a gate-emitter voltage of the measuring semiconductor switch is ascertained on the basis of an area-adjusted current value, which results from a product of the measuring current and a quotient of the first area and the second area, and on the basis of a predefined transfer function of the semiconductor switch, which function predefines a relationship between an internal gate-emitter voltage of the semiconductor switch and a collector current of the semiconductor switch. The area-adjusted current value is correspondingly ascertained as follows:

$$Isa = Is \times \frac{A 2}{A 1}$$

where Isa represents the area-adjusted current value, Is the measuring current, A2 the area of the main semiconductor switch and A1 the area of the measuring semiconductor switch.

The internal gate-emitter voltage on which the transfer function is based preferably represents a voltage free from parasitic influences on the gate-emitter voltage. The transfer function is stored, for example, in the form of representative data in a memory unit that is connected to the evaluation unit via information technology.

In a fifth step of the method according to the present invention, a gate-emitter voltage of the main semiconductor switch is ascertained by adding, to the gate-emitter voltage of the measuring semiconductor switch, a total ohmic voltage drop between the emitter of the measuring semiconductor switch and the emitter of the main semiconductor switch and, in particular, additionally an inductive voltage drop between the emitter of the measuring semiconductor switch and the emitter of the main semiconductor switch.

The inductive voltage drop ΔU_{ge,M} is preferably calculated as follows:

$$Δ {U}_{ge , M} = M \times \frac{dIsa}{dt}$$

where M is an inductive coupling between wirings of the measuring semiconductor switch and wirings inside and outside the semiconductor switch or a chip and/or a module into which the semiconductor switch is integrated.

The gate-emitter voltage of the main semiconductor switch U_{ge,S2} is calculated for example as follows:

$${U}_{ge , S 2} = {U}_{ge , S 1} + Δ {U}_{ge , R} + Δ {U}_{ge , M}$$

where U_{ge,S1} represents the internal gate-emitter voltage of the measuring semiconductor switch ascertained in the fourth step, ΔU_{ge,R} the total ohmic voltage drop between the emitter terminal of the measuring semiconductor switch and the emitter terminal of the main semiconductor switch and ΔU_{ge,M} the inductive voltage drop ascertained as above. A specific composition of the total ohmic voltage drop ΔU_{ge,R} will be explained in more detail below in the course of the description of advantageous embodiments of the present invention.

In a sixth step of the method according to the present invention, a collector current of the main semiconductor switch is finally ascertained on the basis of the ascertained gate-emitter voltage of the main semiconductor switch and the transfer function of the semiconductor switch. It should be noted that the transfer function used in the fourth step is the same transfer function used in the sixth step.

Preferred developments of the present invention are disclosed herein.

Further preferably, the main semiconductor switch and the measuring semiconductor switch are in each case designed as an Substitute Specification IGBT, as a MOSFET, or as a bipolar transistor, without thereby restricting them to the semiconductor types mentioned.

The total ohmic voltage drop taken into account in the fifth method step preferably results from the voltage drop across the measuring resistor and in particular preferably additionally from a voltage drop across a wiring resistor and/or across a bond resistor. The wiring resistance results from a resistance of lines used to connect the measuring resistor to the semiconductor switch. The wiring resistance can be ascertained, for example, by means of a separate measurement of the lines carried out beforehand and/or on the basis of information regarding the dimensioning of the lines. The bond resistance results from a resistance of bond wires via which the externally accessible terminals of the measuring semiconductor switch (via which the measurement is effected) are connected to internal terminals of the measuring semiconductor switch. By ascertaining the corresponding voltage drops during the measurement on the basis of the respective resistance values of the wiring resistor and the bond resistor and taking these into account when ascertaining the total voltage drop, the collector current of the main semiconductor switch can be ascertained with a particularly high degree of accuracy. The total ohmic voltage drop ΔU_{ge,R} is preferably calculated as follows:

$$Δ {U}_{ge , R} = Is \times ( {R}_{s} + {R}_{w} + {R}_{b} )$$

where Is represents the measuring current, Rs the resistance value of the measuring resistor, Rw the wiring resistance and Rb the bond resistance.

In a preferred configuration of the present invention, in addition to measuring the voltage drop across the measuring resistor, a measurement of a common-mode interference is carried out in order to compensate for the influence of the common-mode interference on the voltage drop. For this purpose, a first measuring line of the measuring arrangement is, for example, permanently connected to the emitter terminal of the main semiconductor switch, while a second measuring line of the measuring arrangement is, for example, alternately connected to the emitter terminal of the measuring semiconductor switch and to the emitter of the main semiconductor switch. If a voltage drop other than zero is measured in the case where the two measuring lines are in each case connected to the emitter of the main semiconductor, this value can be used to compensate for the actual voltage measurement across the measuring resistor. As a result, the accuracy in ascertaining the collector current of the main semiconductor switch on the basis of the method according to the present invention can be further improved. It is particularly advantageous if the switching between the two measuring points to be measured by the second measuring line is effected on the basis of a changeover switch, so that an arrangement of the two measuring lines is not changed between the two measurements, in order to not change an inductive coupling between the measuring lines and/or to implement a particularly rapid compensation of common-mode interferences.

According to an example embodiment of the present invention, preferably, the measurement of the voltage drop across the measuring resistor is carried out multiple times and the value of the voltage drop is preferably ascertained on the basis of respective individual results of the multiple measurements and in particular on the basis of an average value being formed over the respective individual results, in order to filter out any interference that may be present.

In an advantageous configuration of the present invention, the semiconductor switch, which comprises the main semiconductor switch and the measuring semiconductor switch, is designed as a semiconductor chip and/or is integrated into a semiconductor module, which in particular comprises at least one further main semiconductor switch. In the latter case in particular, as a rule, a conventional individual measurement of the collector current of the main semiconductor switch is no longer possible, which is why the method according to the present invention can be used particularly advantageously in this case.

In a further advantageous configuration of the present invention, the method further comprises a step for calibrating the measuring arrangement, on the basis of which the current and voltage values for ascertaining the collector current of the semiconductor switch are measured by measuring a collector current of the semiconductor switch, in order to ascertain a deviation between the measured collector current and the collector current ascertained on the basis of the measuring semiconductor switch. The ascertained deviation is subsequently used for calibrating the measuring arrangement.

According to an example embodiment of the present invention, the calibration of the measuring arrangement is preferably effected by adjusting the wiring resistance in order to substantially equalize the measured collector current and the ascertained collector current in a steady state of the semiconductor switch and/or by adjusting an inductance, which causes the inductive voltage drop, so that respective points in time of a rising edge and/or a falling edge of the measured collector current (which is generated by a switch-on process and a subsequent switch-off process) and the ascertained collector current substantially coincide.

Preferably, according to an example embodiment of the present invention, the calibration is effected on the basis of the same control of the semiconductor switch with which the collector current is ascertained, wherein in particular a sequence of the rising and/or falling edge of the collector current is checked for plausibility by comparing an expected sequence of the edges with the measured sequence of the edges.

In a further advantageous configuration of the present invention, in a case in which a semiconductor module comprises a plurality of semiconductor switches, the calibration is effected by switching on only that main semiconductor switch of the semiconductor module whose measuring semiconductor switch is used or accessible for ascertaining the collector current of the semiconductor switch according to the present invention. In a case in which a plurality of measuring semiconductor switches are accessible from outside for a measurement according to the present invention, the method according to the present invention can advantageously be applied to further main semiconductor switches corresponding to the measuring semiconductor switches, in order to be able to ascertain any deviations that may exist between the respective collector currents of the main semiconductor switches. In any case, this requires that control of the respective semiconductor switches of the plurality of semiconductor switches in such a module can be effected independently of one another.

### BRIEF DESCRIPTION OF THE DRAWINGS

In the following, exemplary embodiments of the present invention are described in detail with reference to the figures.

FIG. 1 is a circuit diagram of an example embodiment of a semiconductor according to the present invention in conjunction with a measuring arrangement according to an example embodiment of the present invention.

FIG. 2A shows an exemplary measuring arrangement for ascertaining common-mode interferences in a first measuring state, according to the present invention.

FIG. 2B shows the exemplary measuring arrangement for ascertaining common-mode interferences in a second measuring state, according to the present invention.

### DETAILED DESCRIPTION OF EXAMPLE EMBODIMENTS

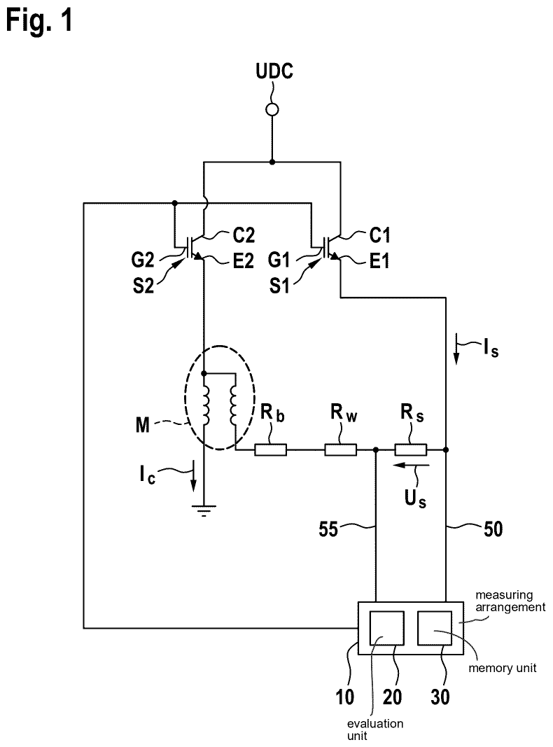

FIG. 1 shows a circuit diagram of an embodiment of a semiconductor according to the present invention in conjunction with a measuring arrangement 10 according to the present invention, on the basis of which a method according to the present invention for measuring a collector current Ic of the semiconductor switch by means of a measuring resistor Rs can be carried out. The semiconductor according to the present invention is designed here as an IGBT.

The measuring arrangement 10 comprises an evaluation unit 20 designed as a microcontroller, a memory unit 30, a first measuring line 50 and a second measuring line 55, wherein the evaluation unit 20 is configured to carry out at least some of the steps of the method according to the present invention.

For this purpose, a resistance value of the measuring resistor Rs is initially measured on the basis of the measuring arrangement 10 and/or on the basis of an arrangement deviating therefrom by means of a four-wire measurement with a high degree of accuracy. The measured value is advantageously stored in the memory unit 30 for subsequent use by the measuring arrangement 10.

The measuring arrangement 10 is connected to the measuring resistor Rs via the measuring lines 50, 55 and is thus configured to measure a voltage drop Us across the measuring resistor Rs in a state in which the measuring resistor Rs is connected between an emitter terminal E1 of a measuring semiconductor switch S1 of the semiconductor switch and an emitter terminal E2 of a main semiconductor switch S2 of the semiconductor switch.

In addition, respective collector terminals C1, C2 of the two semiconductor switches S1, S2 and respective gate terminals G1, G2 of the two semiconductor switches S1, S2 are electrically connected to one another, while a direct voltage UDC is applied between the collector terminals C1, C2 and the emitter terminals E1, E2.

The main semiconductor switch S1 comprises a first area, which here is larger by a factor of 1000 than a second area of the measuring semiconductor switch S2.

The measuring arrangement 10 is configured to carry out the measurement of the voltage drop Us multiple times and to calculate a resulting voltage drop Us by means of an average value being formed over the respective measurement results.

The measuring arrangement 10 is further configured to calculate a measuring current Is from a quotient of the voltage drop Us across the measuring resistor Rs and the resistance value of the measuring resistor Rs.

In addition, the measuring arrangement 10 is configured to ascertain a gate-emitter voltage of the measuring semiconductor switch S1 on the basis of an area-adjusted current value, which results from a product of the measuring current Is and a quotient of the first area and the second area, and on the basis of a predefined transfer function of the semiconductor switch, which function predefines a relationship between an internal gate-emitter voltage of the semiconductor switch and a collector current Ic of the semiconductor switch.

The transfer function is preferably a transfer function ascertained in advance, which can be stored in the memory unit 30 in the form of data representing the transfer function.

The measuring arrangement 10 is further configured to ascertain a gate-emitter voltage of the main semiconductor switch S2 by adding, to the gate-emitter voltage of the measuring semiconductor switch S2, a total ohmic voltage drop between the emitter E1 of the measuring semiconductor switch S1 and the emitter E2 of the main semiconductor switch S2 and an inductive voltage drop between the emitter E1 of the measuring semiconductor switch S1 and the emitter E2 of the main semiconductor switch S2.

Finally, the measuring arrangement 10 is configured to ascertain a collector current Ic of the main semiconductor switch on the basis of the ascertained gate-emitter voltage of the main semiconductor switch S2 and the transfer function of the semiconductor switch.

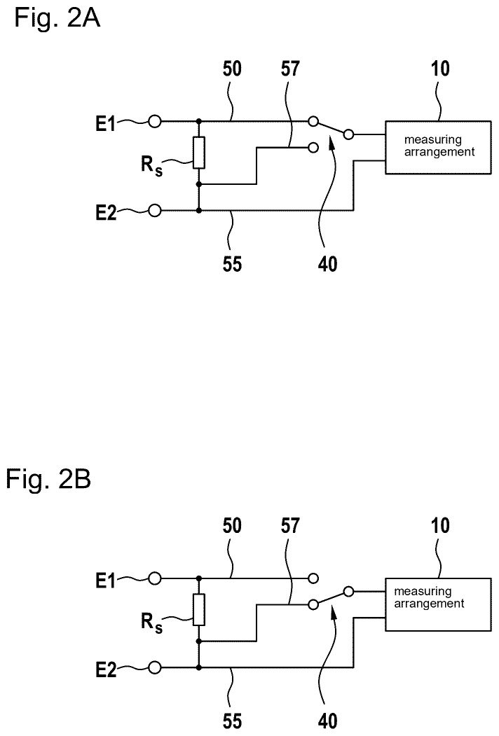

FIG. 2A shows an exemplary measuring arrangement 10 for ascertaining common-mode interferences in a first measuring state.

In this first measuring state, a measuring resistor Rs, which is connected between an emitter terminal E1 of a measuring semiconductor switch S1 (see FIG. 1) and an emitter terminal of a measuring semiconductor switch S2 (see FIG. 1), is measured via a first measuring line 50 and a second measuring line 55, since a changeover switch 40 comprises a first switching position.

FIG. 2B shows the exemplary measuring arrangement 10 from FIG. 2A for ascertaining common-mode interferences in a second measuring state.

In this second measuring state, measurements are taken via the first measuring line 50 and via a third measuring line 57 in each case on the side of the measuring resistor Rs which is connected to the emitter E2 of the main semiconductor switch S2, since the changeover switch 40 comprises a second switching position.

Information regarding a common-mode interference measured in this measurement state can advantageously be used to compensate for the measurement in FIG. 2A, in order to increase the accuracy of the measuring method according to the present invention.

1-10. (canceled)

11. A method for measuring a collector current of a semiconductor switch using a measuring resistor, the method comprising the following steps:
ascertaining a resistance value of the measuring resistor;
measuring a voltage drop across the measuring resistor in a state in which the measuring resistor is connected between an emitter terminal of a measuring semiconductor switch of the semiconductor switch and an emitter terminal of a main semiconductor switch of the semiconductor switch, wherein:
respective collector terminals of the measuring semiconductor switch and the main semiconductor switch and respective gate terminals of the measuring semiconductor switch and the main semiconductor switch are electrically connected to one another,
a direct voltage is applied between the collector terminals and the emitter terminals, and
the main semiconductor switch has a first area that is larger than a second area of the measuring semiconductor switch,
ascertaining a measuring current from a quotient of the voltage drop across the measuring resistor and the resistance value of the measuring resistor;
ascertaining a gate-emitter voltage of the measuring semiconductor switch based on:
an area-adjusted current value, which results from a product of the measuring current and a quotient of the first area and the second area, and
a predefined transfer function of the semiconductor switch, the predefine transfer function predefining a relationship between an internal gate-emitter voltage of the semiconductor switch and a collector current of the semiconductor switch,
ascertaining a gate-emitter voltage of the main semiconductor switch by adding, to the gate-emitter voltage of the measuring semiconductor switch, a total ohmic voltage drop between the emitter of the measuring semiconductor switch and the emitter of the main semiconductor switch and additionally an inductive voltage drop between the emitter of the measuring semiconductor switch and the emitter of the main semiconductor switch; and
ascertaining a collector current of the main semiconductor switch based on the ascertained gate-emitter voltage of the main semiconductor switch and the transfer function of the semiconductor switch.

12. The method according to claim 11, wherein each of the main semiconductor switch and the measuring semiconductor switch is an IGBT, or a MOSFET, or a bipolar transistor.

13. The method according to claim 11, wherein the total ohmic voltage drop results from the voltage drop across the measuring resistor and from a voltage drop across a wiring resistor and/or across a bond resistor.

14. The method according to claim 11, wherein in addition to measuring the voltage drop across the measuring resistor, a measurement of a common-mode interference is carried out to compensate for an influence of the common-mode interference on the voltage drop across the measuring resistor.

15. The method according to claim 11, wherein the measurement of the voltage drop across the measuring resistor is carried out multiple times and a value of the voltage drop is ascertained based on respective individual results of the multiple measurements and based on an average value formed over the respective individual results.

16. The method according to claim 11, wherein the semiconductor switch, which includes the main semiconductor switch and the measuring semiconductor switch:
is a semiconductor chip, and/or
is integrated into a semiconductor module, which includes at least one further main semiconductor switch.

17. The method according to claim 11, further comprising calibrating a measuring arrangement, based on which current and voltage values for ascertaining the collector current of the semiconductor switch are measured by:
a collector current of the semiconductor switch being measured in order to ascertain a deviation between the measured collector current and the collector current ascertained based on the measuring semiconductor switch, and
an ascertained deviation being used for calibrating the measuring arrangement.

18. The method according to claim 17, wherein the measuring arrangement is calibrated by:
adjusting a wiring resistance in order to substantially equalize the measured collector current and the ascertained collector current in a steady state, and/or
adjusting an inductance, which causes the inductive voltage drop, so that respective points in time of a rising edge and/or a falling edge of the measured collector current and the ascertained collector current substantially coincide.

19. The method according to claim 17, wherein the calibration is effected based on the same control of the semiconductor switch with which the collector current is ascertained, wherein a sequence of the rising and/or falling edge of the collector current is checked for plausibility.

20. The method according to claim 17, wherein a semiconductor module includes a plurality of semiconductor switches, the calibration is effected by switching on only that main semiconductor switch of the semiconductor module whose measuring semiconductor switch is used for ascertaining the collector current of the semiconductor switch.
